(19) United States
(12) Patent Application Publication
(10) Pub. No.: US 2009/0151770 A1
(43) Pub. Date: Jun. 18, 2009

(54) METHOD AND MATERIAL FOR COUPLING SOLAR CONCENTRATORS AND PHOTOVOLTAIC DEVICES

(75) Inventors: KEVIN R. GIBSON, Redwood City, CA (US); Alelie Funcell, Fremont, CA (US); Abhay Maheshwari, Monte Sereno, CA (US); Shirish Shah, San Ramon, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Solaria Corporation, Fremont, CA (US)

(21) Appl. No.: 12/331,429

(22) Filed: Dec. 9, 2008

Related U.S. Application Data
(60) Provisional application No. 61/013,254, filed on Dec. 12, 2007.

(51) Int. Cl. H01L 31/052; B32B 37/00; H01L 21/02; H01L 31/18

(52) U.S. Cl. 136/246; 156/242; 156/245; 438/98; 257/E21.002

(57) ABSTRACT

A method and system for manufacturing an integrated concentrator photovoltaic device is disclosed. In an embodiment, the invention includes a one step process using a sheet of coupling material provided in a pre-arranged pattern to couple an array of photovoltaic members to an array of respective optical concentrating members. In another embodiment, the invention includes an integrated concentrator photovoltaic device made by coupling a photovoltaic member and an optical concentrating member together through an encapsulant or coupling layer formed from a sheet member of coupling materials possessing a pre-arranged pattern

### CROSS-REFERENCES TO RELATED APPLICATIONS

This application claims priority to U.S. Provisional Application No. 61/013,254, filed Dec. 12, 2007, commonly assigned, and incorporate herein by reference. This application is related to “Method And Resulting Device For Curing A Polymer Material For Solar Module Applications,” application Ser. No. 11/753,546, filed May 24, 2007, and is incorporated herein by reference.

### BACKGROUND OF THE INVENTION

The present invention relates generally to solar energy techniques. In particular, the present invention provides a method and a material used to couple a plurality of photovoltaic elements with a plurality of respective concentrating elements. More particularly, the present invention provides a method and device including a sheet of material, which can be free standing, to couple a plurality of photovoltaic members to a plurality of respective optical concentrating members. According to a specific embodiment, the sheet of material can include a plurality of coupling elements arranged in predetermined patterns to couple the plurality of optical concentrating elements to the plurality of photovoltaic members (e.g., elements or strips). Merely by way of example, the present invention can be applied to manufacturing of photovoltaic cells with lowered costs and increased efficiencies. The invention has been applied to solar panels, commonly termed modules, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use come from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are costly to manufacture. Depending upon the geographic region, financial subsidies from governmental entities for purchasing solar panels are often needed for the technology for solar power to compete with electricity generated from more conventional means from public power companies. In addition, availability of solar panels can be scarce, subject to fluctuations in the broader world market.

From the above, it seems that a method and a system for improved manufacturing processes associated with lost cost and efficient solar devices is highly desirable.

### BRIEF SUMMARY OF THE INVENTION

The present invention relates generally to solar energy techniques. In particular, the present invention provides a method and a structure to couple a plurality of photovoltaic elements with a plurality of respective concentrating elements. More particularly, the present invention provides a method and device including a sheet of material, which can be free standing, to couple a plurality of photovoltaic members to a plurality of optical concentrating members. According to a specific embodiment, the sheet of material can include a plurality of coupling elements arranged in predetermined patterns to couple the plurality of optical concentrating elements to the plurality of photovoltaic members (e.g., elements or strips). Merely by way of example, the present invention provides a method and a structure for manufacturing photovoltaic cells with lowered costs and improved efficiencies. The invention has been applied to solar panels, commonly termed modules, but it would be recognized that the invention has a much broader range of applicability.

According to an embodiment of the present invention, a method for fabricating a solar device is provided. An exemplary method includes providing a photovoltaic member having a plurality of photovoltaic elements. The method includes providing a sheet member. In a preferred embodiment, the sheet member is configured to align the plurality of photovoltaic elements to respective plurality of concentrating elements and also serves as an optical coupling material. In a specific embodiment, the sheet member includes a predefined pattern of coupling elements made of a coupling material. The sheet member provides an optical concentrating member having a plurality of concentrating elements in a specific embodiment. According to a specific embodiment, the plurality of photovoltaic elements, the plurality of concentrating elements, and the plurality of coupling elements may be arranged in arrays.

An exemplary method includes positioning the sheet member between the photovoltaic member and the optical concentrating member. According to the embodiment, the sheet member may be positioned in such a way that the plurality of coupling elements on the sheet member are aligned to the respective plurality of photovoltaic elements on the photovoltaic member. According to a specific embodiment, the sheet member is in physical contact with the photovoltaic member. According to another embodiment, the sheet member may be positioned in such a way that the plurality of coupling elements on the sheet member and the plurality of concentrating elements on the optical concentrating member are aligned with each other. According to another specific embodiment, the sheet member is in physical contact with the optical concentrating member.

An exemplary method includes processing the sheet member positioned between the photovoltaic member and the optical concentrating member using a curing process. According to an embodiment, the curing process allows the photovoltaic member to be coupled to the optical concentrating member through an encapsulant or coupling layer provided by the sheet member. In a specific embodiment, the curing process transforms the coupling material from a thermal plastic state to a thermal set state. Of course there can be other variations, modifications, and alternatives.

According to an embodiment, the method provides an encapsulant or coupling layer that increases the efficiency of light transmission from a first concentrating element to a first photovoltaic element. The encapsulant or coupling layer can be used to reduce a thermal mismatch effect between the first photovoltaic element and the first concentrating element. The encapsulant or coupling layer can also be used to provide for an environmental barrier between the photovoltaic member and the concentrating member. Of course there can be other variations, modifications, and alternatives.

According to an embodiment, an exemplary curing process includes applying a force to cause a force profile to the sheet member over a specified period of time. An exemplary curing process involves applying a temperature profile to the sheet member over a specified period of time. An exemplary curing process can also involve applying specific chemicals to the sheet member over a specified period of time. In a specific embodiment, the coupling material on the sheet member can also include an optical coupling material, such as ethyl vinyl acetate (EVA), PVA, and APU.

According to an embodiment, when an exemplary sheet member is placed between the photovoltaic member and the optical concentrating member, the sheet member is placed on the photovoltaic member first and the concentrator member is placed on the sheet member next. According to another embodiment, the sheet member is placed on the concentrator first and the photovoltaic member is placed on the sheet member second next. Of course, there can be other variations, modifications, and alternatives.

An exemplary photovoltaic member includes a plurality of electrodes. According to an embodiment, the plurality of electrodes is adapted to couple with the plurality of photovoltaic elements. According to another embodiment, the plurality of electrodes is adapted to conduct power generated at the plurality of photovoltaic elements away from the plurality of photovoltaic elements.

According to an embodiment, an exemplary sheet member includes a frame-structure portion and a patterned portion. The patterned portion includes a predefined pattern of coupling elements. An exemplary frame-structure portion is adapted to allow the sheet member to be positioned and aligned between the photovoltaic member and the concentrating member. According to an embodiment, the frame-structure portion may be coupled to the patterned portion through a filler material surrounding the plurality of coupling elements in the patterned portion. According to another embodiment, the frame-structure portion may be coupled to the patterned portion through a connecting portion on the frame-structure.

An exemplary frame-structure portion is adapted to be removed from the patterned portion. The frame-structure portion may be removed before or after the sheet member has been cured. The frame-structure portion may be removed by a snapping motion or force. The frame-structure portion may be removed by a twisting motion or force.

According to an embodiment, the patterned portion includes a plurality of spacing elements. The spacing elements may be cylindrical or spherical in shape. The spacing elements are more rigid than the coupling material and help to create a minimum thickness to an encapsulant or coupling layer created by the sheet member. The spacing elements also help to maintain a uniform thickness to an encapsulant or coupling layer created by the sheet member.

Many benefits are achieved by way of the present invention over conventional techniques. For example, the present method and device provides an easy solution to simplify conventional manufacturing processes without substantial modifications to conventional equipment and processes. In a preferred embodiment, the present solar cell is manufactured using a sheet of coupling material to couple together a photovoltaic member and an optical concentrating member. In a preferred embodiment, the sheet member is configured to align the plurality of photovoltaic elements to respective plurality of concentrating elements and also serves as an optical coupling material.

According to an embodiment, an exemplary process bypasses the requirement of physically assembling light concentrator elements onto photovoltaic silicon bearing wafer materials. Physically assembling light concentrator elements can be costly and can increase the complexities of the manufacturing process, especially on a large scale. The exemplary process can increase the efficiencies of silicon panels as well as decrease the costs and complexities of manufacturing silicon panels.

According to an embodiment, the present invention can leverage processes that rely upon conventional technology such as silicon materials, although other materials can also be used. Preferably, an exemplary process or system provides for an improved solar cell that is less costly and easier to manufacture and handle. Such solar cell uses a plurality of photovoltaic members or regions, which are sealed within one or more substrate structures according to a preferred embodiment. A preferred embodiment provides for a method and completed solar cell structure involving a plurality of photovoltaic strips free and clear from a module or panel assembly that are assembled together with a reduced number of steps.

According to a preferred embodiment, the present method and cell structures are light weight and not detrimental to building structures and the like. According to a specific embodiment, the weight is about the same or slightly more than conventional solar cells at a module level according to a specific embodiment. According to another specific embodiment, one or more of the solar cells have less silicon per area (e.g., 80% or less, 50% or less) than conventional solar cells.

Depending upon the embodiment, one or more of these benefits may be achieved. These and other benefits will be described in more detail throughout the present specification and more particularly below.

### BRIEF DESCRIPTION OF THE DRAWINGS

FIG. 1 is a simplified diagram illustrating an optical concentrating member with an array of concentrating elements overlaying a photovoltaic member according to an embodiment of the present invention;

FIG. 2 shows a simplified diagram illustrating a plurality of optical concentrating members with a plurality of concentrating elements and a side profile of two concentrating elements according to an embodiment of the present invention;

FIG. 3 is a simplified close-up diagram of a side profile views of an optical concentrating member with an array of concentrating elements;

FIG. 4 is a simplified close-up diagram of a concentrating element overlaid with a plurality of exemplary light paths according to an embodiment of the present invention;

FIG. 5 is a simplified diagram of a concentrating element integrated with a basic photovoltaic element according to an embodiment of the present invention;

FIG. 6 shows a simplified diagram of a sheet member adapted to couple together an optical concentrating member and a photovoltaic member according to an embodiment of the invention;

FIG. 7 shows a simplified close-up diagram of concentrating element, a coupling element, and a photovoltaic element according to an embodiment;

FIG. 8 shows a simplified diagram of a sheet member according to another embodiment;

FIG. 9 shows two simplified diagrams of two embodiments of spacer elements used in a coupling element according to an aspect of the invention; and

FIG. 10 shows a simplified flow diagram of an exemplary process using a sheet member to couple a photovoltaic member and an optical concentrating member according to an aspect of the invention.

### DETAILED DESCRIPTION OF THE INVENTION

Embodiments according to the present invention relates generally to solar energy techniques. In particular, the present invention provides a method and material used to couple a plurality of photovoltaic elements to a plurality of respective concentrating elements. More particularly, the present invention provides a method and device including a sheet member, which can be free standing, to couple a plurality of photovoltaic members to a plurality of respective optical concentrating members. According to a specific embodiment, the sheet member includes a plurality of coupling elements arranged in predetermined patterns to couple the plurality of optical concentrating elements to the plurality of photovoltaic members (e.g., elements or strips). Merely by way of example, the present invention provides a cost efficient method for manufacturing photovoltaic cells with increased efficiencies. The invention has been applied to solar panels, commonly termed modules, but it would be recognized that the invention has a much broader range of applicability.

The diagrams shown herein are merely by way of examples, which should not unduly limit the scope of the claims herein. One of ordinary skill in the art would recognize many variations, modifications, and alternatives.

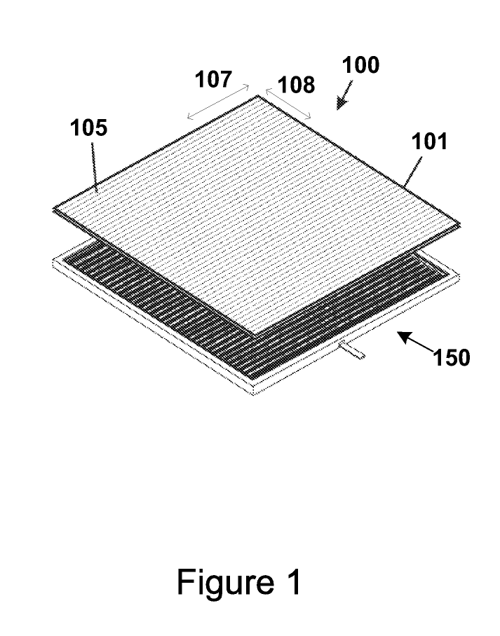

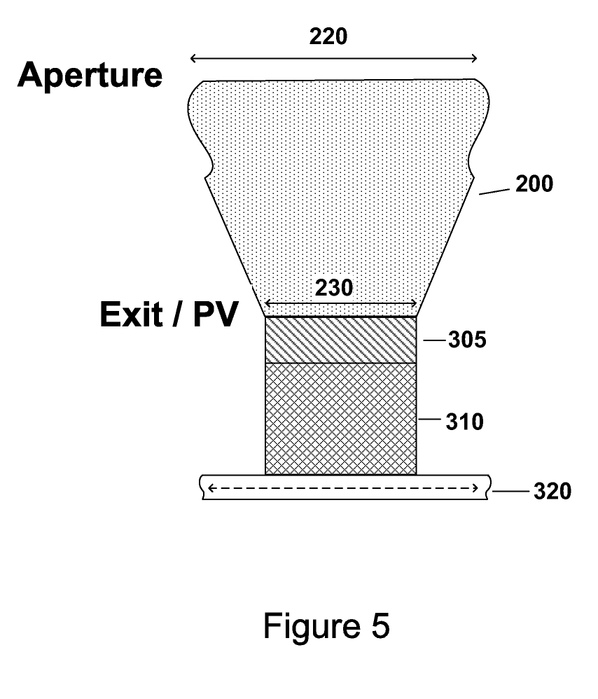

FIG. 1 shows a simplified diagram illustrating a solar panel 100 including a front cover 101 and an array of concentrating elements 105 overlaying a photovoltaic component 150 according to an embodiment of the present invention. The photovoltaic component may include a back cover, an array of photovoltaic strips or elements, and an encapsulant (shown later in more detailed in FIG. 5) in a specific embodiment. In a preferred embodiment, front cover 101 includes an array of concentrating elements 105. An exemplary array of concentrating elements 105 may be characterized by a first length characterizing a dimensional extent of a unit along a first direction 107 and a second length characterizing the size of the gap separating each unit of concentrating element from each other along a second direction 108.

According to an aspect of the current invention, a portion of front cover 101 includes light concentrators that may be molded onto an array of photovoltaic cells to form an array of integrated concentrator photovoltaic cells. Depending upon the specific embodiments, the front cover member may be created rigid and made of a polymer material, a glass material, a multilayered construction, etc. According to an embodiment, a rigid front cover member is manufactured by one of a variety of processes including injection, transfer, compression, or extrusion.

In a specific embodiment, the front cover member is optically clear and can be characterized by an index of refraction. In a specific embodiment, the index of refraction can be 1.4 or greater. An exemplary front cover member may be provided by a material with a light transmissivity of 88% or greater. According to another specific embodiment, a front cover member may be provided by a material with a light absorption of 4% or less. Other variations, modifications, and alternatives as contemplated by a person of ordinary skill in the art also exist.

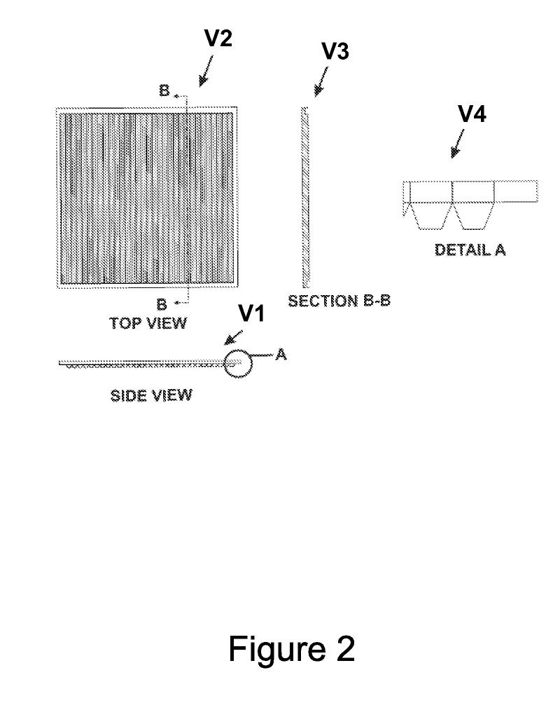

FIG. 2 shows a simplified diagram illustrating several perspectives of a front cover and the array of concentrating elements. According to a current embodiment, the front cover is illustrated by a side view V1, a top view V2, and a cross section view V3 across section “B-B,” and a close-up profile view V4 including two concentrating elements. Of course there can be other modifications, variations, and alternatives.

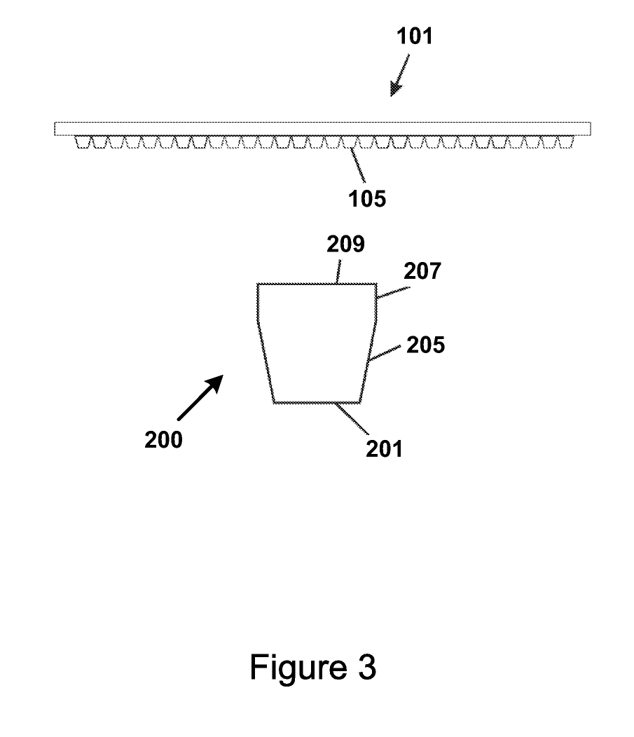

FIG. 3 shows a simplified diagram illustrating a side view of a front cover 101 with a plurality of concentrating elements 105 according to an embodiment of the present invention. A close-up of side profile of a concentrating element 200 is also illustrated. As shown, an exemplary concentrating element includes a trapezoidal shaped member, where the trapezoidal shaped member has a bottom surface 201 coupled to a pyramidal shaped region that defined by a lower surface 205 and an upper surface 207. According to the embodiment, the trapezoidal shaped member has an upper region defined by a surface 209 which may be co-extensive of front cover 101. Each concentrator element 200 may be spatially disposed to be parallel to each other, according to a specific embodiment. An exemplary concentration element 200 also includes a first reflective side 207 and an aperture region 209.

According to an embodiment, a “trapezoidal” or “pyramidal” shaped member includes embodiments with straight, curved, or a combination of straight and curved walls. For example, the trapezoidal or pyramidal surfaces defined by surfaces 205 and 207 may be curved and not necessarily straight as illustrated in FIG. 3. Also, depending upon the specific embodiment, the concentrating elements may be located near the front cover, integrated as part of the front cover, or be coupled to the front cover. According to a preferred embodiment, the front cover and concentrating elements are molded and integrated with photovoltaic members, where the integrated unit is adapted to convert light energy into electrical energy.

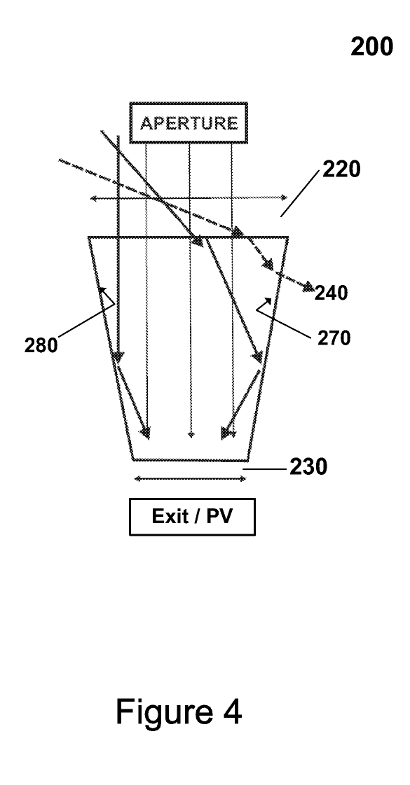

FIG. 4 shows a simplified diagram of a concentrator element 200 according to an embodiment of the present invention. Several aspects of the concentrator element are illustrated in detailed. The concentrator element includes an aperture region 220 where light enters the concentrator element and an exit region 230 where light exits. It shows how light rays entering a concentrator may be reflected and directed toward exist region 230. Due to inefficiencies, some of the energy of light entering aperture region 220 may not exit the concentrator through exit region 230 but in a direction 240. In a specific embodiment, the efficiencies of a concentrator to direct light from the aperture toward the exist region can be 90% or higher by using a combination of index of refraction, surface roughness, encapsulant or coupling material, and others. Of course one skilled in the art would recognize other modifications, variations, and alternatives.

Referring to FIG. 4, the concentrating element is characterized by a light entrance aperture area and a light exit area. In a specific embodiment, the ratio of exit area to aperture area is about 0.8 or less. In certain embodiments, the ratio of exit area to aperture area can be about 0.5. The concentrating element has a height. In a specific embodiment, the concentrating element has a height of about 7 mm or less. According to another embodiment, a first reflective side 270 and a second reflective side 280 of the concentrating element may be characterized by a surface roughness. In a specific embodiment, the surface roughness of the first reflective side and the second reflective side is less than about 120 nanometers RMS. According to another specific embodiment, the surface roughness has a dimension value of about 10% of a wavelength of a light entering the aperture regions. An exemplary first reflective side and the second reflective side may be adapted to provide for total internal reflection of light entering the aperture region.

According to another specific embodiment, an exemplary concentrating element is characterized by reflectivity, durability, and refractivity of coatings on one or more of its surface regions. An exemplary concentrating element includes an anti-reflective coating for improved efficiency. Another exemplary concentrating element includes a coating for improving durability of the concentrating element. Another exemplary concentrating element includes coatings having a refractive index of about 1.45 or greater.

FIG. 5 shows a simplified diagram of a concentrator unit integrated with a basic photovoltaic unit according to an embodiment of the present invention. According to an exemplary embodiment, an integrated molded concentrator photovoltaic element includes a concentrator element 200, an encapsulant 305, an energy conversion element (or photovoltaic element) 310 such as a photovoltaic strip, and an energy conducting element 320 such as a bus bar. In a preferred embodiment, integrated concentrator 200 is molded directly onto a photovoltaic element. An exemplary integrated concentrator is preferably adapted to efficiently concentrate the light incident at aperture region 220 to an exit region 230 coupled to a photovoltaic member. The photovoltaic element can be one or more photovoltaic strips in a specific embodiment. The bus bar 320 is provided to conduct electric energy generated by the photovoltaic strip when light is brought incident to the element.

Referring again to FIG. 5, an encapsulant layer 305 may be provided to help compensate for the different thermal expansivity between the concentrator material and the photovoltaic material. Encapsulant layer 305 may also be provided to have an efficient transmission of light from the concentrator element 200 to the photovoltaic strip 310. An exemplary concentrator additionally include one or more pocket regions facing the first reflective side or the second reflective side characterized by a refractive index of about 1. According to a specific embodiment, the pocket regions can be configured to allow a total internal reflection of light within the concentrating element from the aperture region to the exit region.

Depending upon the embodiment, the concentrating element may be made of one of several suitable materials. According to an embodiment, the concentrating element can be made of a polymer, glass, or other optically transparent materials, or a combination of these materials. A suitable material can be one that is environmentally stable and can preferably withstand environmental temperatures, weather, and other “outdoor” conditions. Of course there can be other variations, modifications, and alternatives.

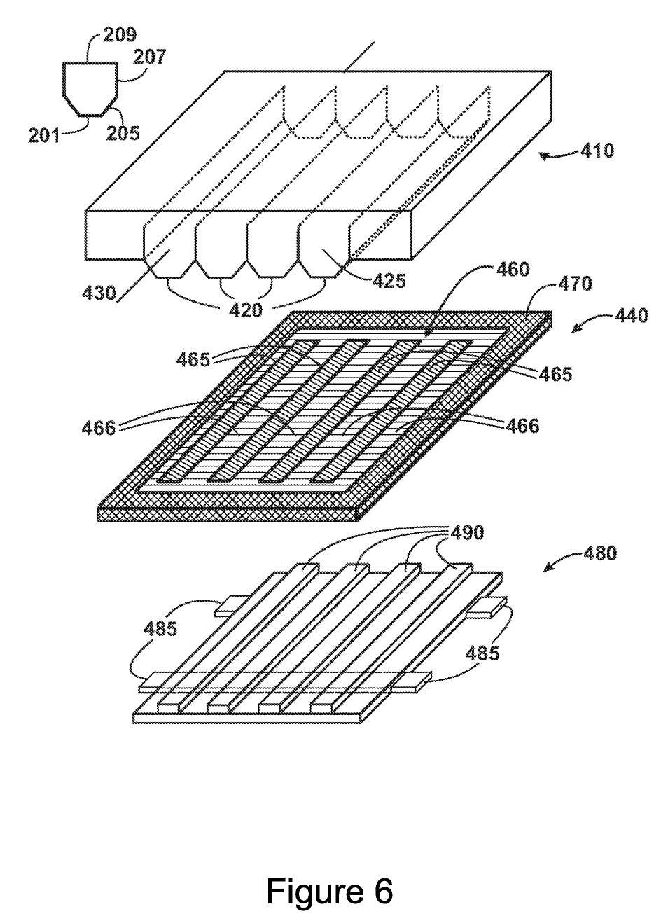

FIG. 6 shows a simplified diagram of a sheet member 440 adapted to couple together an optical concentrating member 410 and a photovoltaic member 480 according to an embodiment of the present invention. In a specific embodiment, sheet member 440 includes a patterned portion 460 located in a center region of the sheet member and a frame-structure portion 470 located around the periphery of the sheet member. Patterned portion 460 can be made of various types of optical coupling materials, including EVA, PVA, or APU depending on the embodiment.

As shown in FIG. 6, patterned portion 460 includes a plurality coupling elements 465 arranged in a predefined pattern. In a specific embodiment, the predefined pattern of coupling elements 465 is made of a coupling material. Predefined pattern of coupling elements 465 on patterned portion 460 provides a matching pattern of coupling contacts for sheet member 440 to couple optical concentrating member 410 to photovoltaic member 480. Patterned portion 460 further includes filler region 466 surrounding the plurality of coupling elements 465. In a specific embodiment, filler region 466 is made of a filler material. In a specific embodiment, frame-structure portion 470 is adapted to allow sheet member 440 to be maneuvered. An external device can maneuver sheet member 440 between photovoltaic member 480 and optical concentrating member 410 such that sheet member 440 is aligned with photovoltaic member 480 and/or optical concentrating member 410.

Referring again to FIG. 6, optical concentrating member 410 includes a plurality of concentrating elements 420. An exemplary concentrating element has a cross section characterized by a pyramidal or trapezoidal cross-sectional shape 425. An exemplary pyramidal or trapezoidal shape includes a bottom surface or exit region 201, a lower side surface or first reflective side 205, an upper side surface or second reflective side 207, and an upper surface or aperture region 209. In additional, a length along a longitudinal axis 430 characterizes the concentrating element.

As shown in FIG. 6, photovoltaic member 480 includes a plurality of photovoltaic elements 490. Photovoltaic elements 490 are adapted to generate electric energy in the presence of an electromagnetic energy. Photovoltaic elements 490 can come in a variety of geometries. For example, as illustrated in FIG. 6, each of the photovoltaic elements 490 has a rectangle shape or as photovoltaic strip. Photovoltaic member 480 includes a plurality of conducting elements 485 coupled to a plurality of concentrating elements 420. Plurality of conducting elements 485 is adapted to conduct electric energy generated at plurality of photovoltaic elements 490 away from the plurality of photovoltaic elements. Plurality of conducting elements 485 may be configured such that each conducting element electrically contacts each of the plurality of photovoltaic elements 490. Plurality of conducting elements 485 may also be configured such that each conducting element electrically contacts one or some of plurality of photovoltaic elements 490.

Depending on the embodiment, the plurality of photovoltaic elements, the plurality of optical concentrating elements, and the plurality of coupling elements may be arranged in a predefined pattern allowing the plurality of photovoltaic elements, the plurality of optical concentrating elements, and the plurality of coupling elements to be aligned. According to a specific embodiment, the plurality of photovoltaic elements, the plurality of optical concentrating elements, and the plurality of coupling elements are arranged in an array pattern. Of course, there can be other variations, modifications, and alternatives.

According to an embodiment, frame-structure portion 470 is adapted to allow for an external device to manipulate sheet member 440 to align sheet member 440 between photovoltaic member 480 and optical concentrating member 410. In a specific embodiment, sheet member 440 is first positioned in contact with photovoltaic member 480 to form a sheet member-photovoltaic member structure by aligning plurality of photovoltaic elements 490 to the plurality of coupling elements 465. Optical concentrating member 410 is then positioned on the concentrating sheet member-photovoltaic structure such that each of the plurality of concentrating elements 420 is aligned with plurality of coupling elements 465. This triple stack concentrator-sheet member-photovoltaic structure can be further processed to allow sheet member 440 to be permanently bonded to photovoltaic member 480 and optical concentrating member 410. Of course there can be other variations, modifications, and alternatives.

Other exemplary methods of forming the triple stack concentrator-sheet member-photovoltaic structure are envisioned. For example, according to another embodiment, sheet member 440 is placed in contact with optical concentrating member 410 first. Plurality of concentrating elements 420 is aligned with plurality of coupling elements 465. Photovoltaic member 480 is positioned on top of the stacked sheet member-photovoltaic structure such that plurality of photovoltaic elements 490 is aligned with plurality of coupling elements 465. This triple stack concentrator-sheet member-photovoltaic structure is processed such that sheet member 440 couples together photovoltaic member 480 and optical concentrating member 410 permanently.

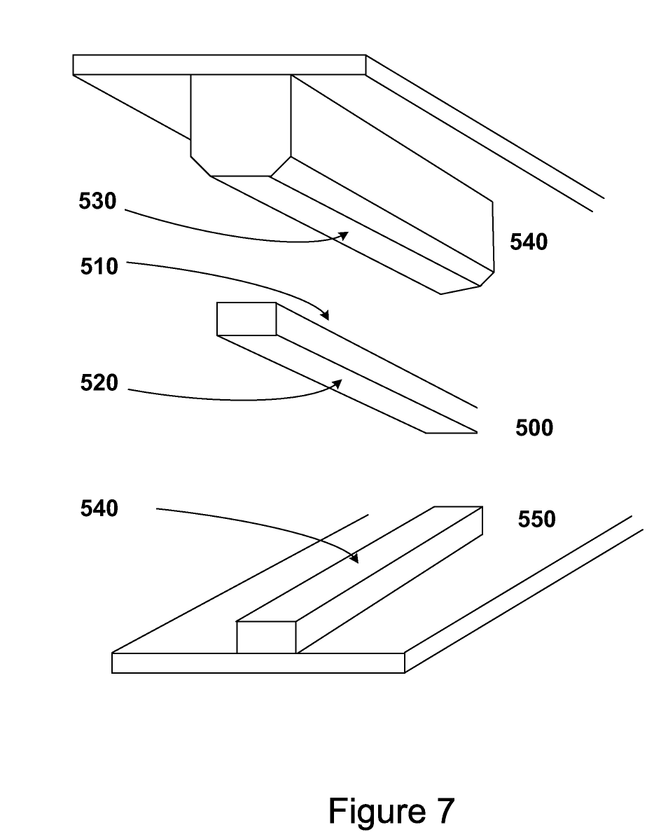

FIG. 7 shows a simplified diagram of a concentrating element 540, a coupling element 500, and a photovoltaic element 550 in more detail according to an embodiment. When a triple-stacked structure of optical concentrating member 410, sheet member 440, and photovoltaic member 480 is formed, top surface 510 of coupling element 500 is coupled with exit region 530 of concentrating element 540. Bottom surface 520 of coupling element 500 is coupled with top surface 540 of photovoltaic element 550. When concentrating element 540, coupling element 500, and photovoltaic element 550 are properly positioned and aligned to form the triple-stacked structure, proper coupling between optical concentrating member 410 and photovoltaic member 480 is achieved. Of course there can be other variations, modifications, and alternatives.

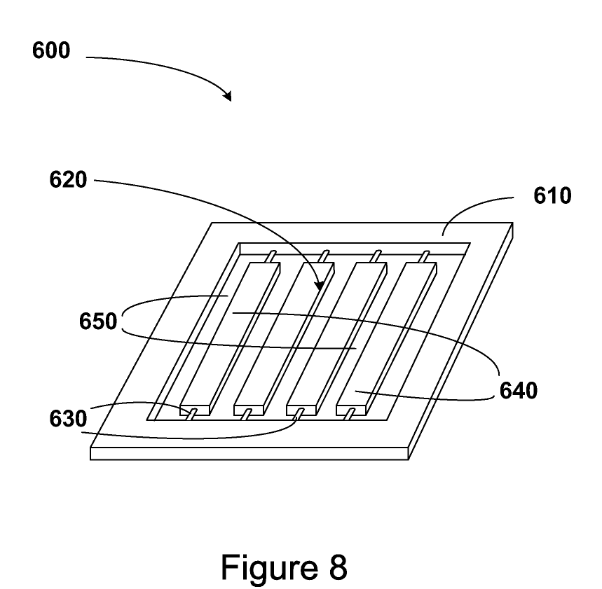

FIG. 8 shows a simplified diagram of a sheet member 600 according to an alternative embodiment of the present invention. Sheet member 600 includes a patterned portion 620, a frame-structure portion 610, and a connector portion 630. Patterned portion 610 includes a plurality of coupling elements 640 arranged in a predefined pattern. Patterned portion 610 includes filler region 650 surrounding the plurality of coupling elements 640. Unlike the embodiment shown in FIG. 6, coupling elements 640 are surrounding by filler region 650 made up of empty spaces or void regions.

In a specific embodiment, each of the plurality of coupling elements can be coupled to the frame member using a plurality of connector elements 630, as shown in FIG. 8 to form the patterned portion of the sheer member. Each of the connector elements 630 can also be adapted to allow patterned portion 610 to be removed from frame-structure portion 620 in a specific embodiment. Connector portion 630 can be broken, for example, by applying an external force or a motion, such as a snapping or a twisting force or motion. Connector portion 630 can be broken before, during, or after the curing process. Of course there can be other variations, modifications, and alternatives.

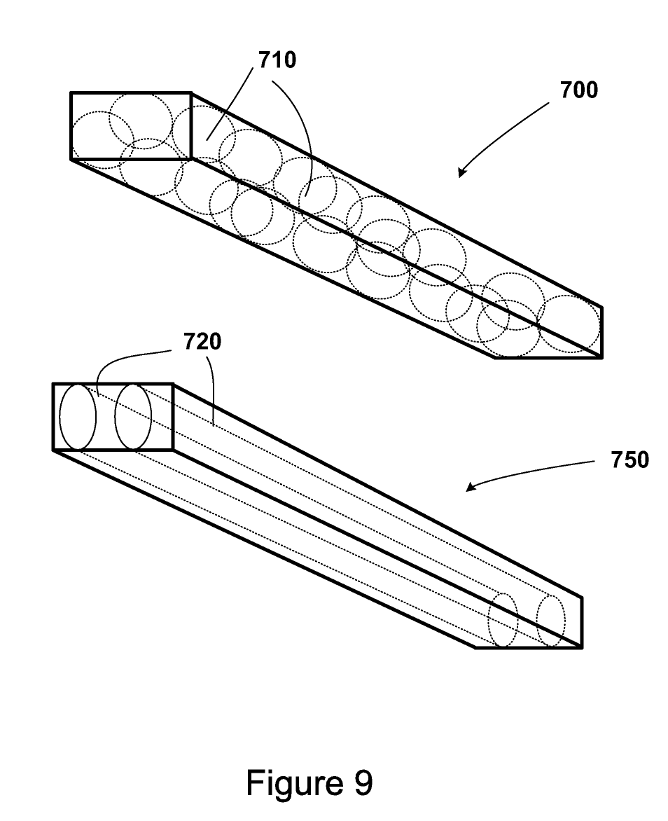

FIG. 9 illustrates spacer elements 710 and 720 used in a coupling element in certain embodiments. The exemplary coupling element 700 includes a plurality of embedded spherical spacer elements 710. An alternative coupling element 750 is also shown. Coupling element 750 includes a plurality of embedded cylindrical spacer elements. These exemplary spacer elements are configured to define a certain minimum thickness associated with an encapsulant or coupling layer. Additionally, these embedded spacer elements maintain a shape and an uniform thickness of the coupling elements in a curing process. Depending on the application, the embedded spacer elements can be provided using materials such as polymer, glass, or other optically transparent materials. The embedded spacer elements may have other geometric shapes depending on the embodiment. Of course there can be other variations, modifications, and alternatives.

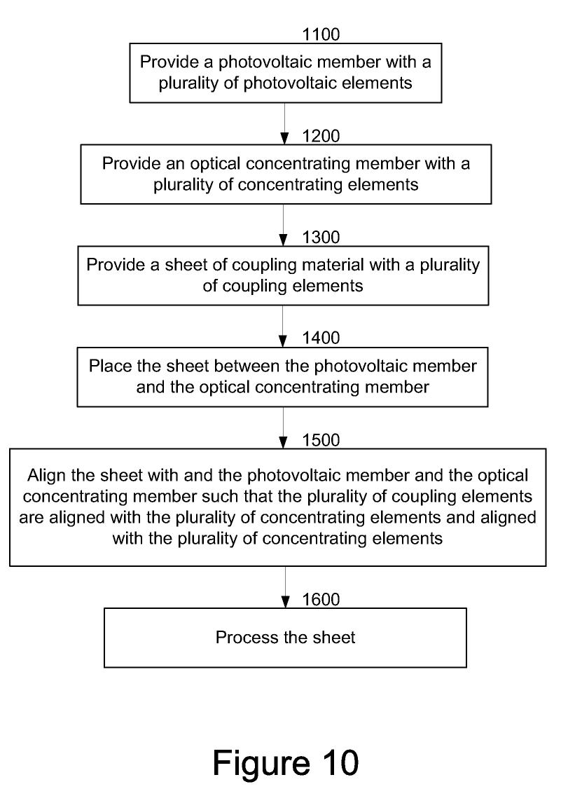

FIG. 10 shows a simplified process flow diagram for coupling a photovoltaic member to an optical concentrating member using a sheet member, which can be patterned, according to an embodiment of the present invention. As shown, Step 1100 includes providing a photovoltaic member with a plurality of photovoltaic elements. Step 1200 includes providing an optical concentrating member with a plurality of concentrating elements provided thereon. Step 1300 includes providing a sheet member with a plurality of coupling elements.

Step 1400 includes placing the sheet member between the photovoltaic member and the optical concentrating member. The process includes placing the sheet member on the photovoltaic member first and followed by placing the concentrator member on the sheet member. Another exemplary process involves placing the patterned sheet member on the concentrator member first followed by placing the photovoltaic member on the sheet member.

Step 1500 includes aligning the sheet member to the photovoltaic member and the optical concentrating member. In a specific embodiment, the sheet member and the optical concentrating member are aligned by aligning the plurality of concentrating elements to the respective plurality of coupling elements. In an alternative embodiment, the sheet member and the photovoltaic member are aligned by aligning the plurality of photovoltaic elements to the respective plurality of coupling elements.

Step 1600 includes processing the sheet member to couple the photovoltaic member to the optical concentrating member using a curing step. The curing step may be selected form various methods for curing coupling materials. The curing step may include removing portions of the coupling materials form the sheet member. In other embodiments, the frame-structure portion of the sheet member can be adapted to maneuver the sheet member and may be removed thereafter. According to another embodiment, all portions of the sheet member except the plurality of coupling elements are removed. Of course there can be other variations, modifications, and alternatives.

In a specific embodiment, the curing process causes the coupling material in the sheet member to change from a thermal plastic state to a thermal set state. The curing process may include the application of a force profile to the sheet member over a specified period of time in a specific embodiment. The curing process may include the application of a temperature profile to the sheet member over a specified period of time. The curing process may include the application of specific chemicals to the sheet member over a specified period of time. In addition, the curing process may also include other types of curing including chemical, mechanical, and radiation based processes. As an example, the curing processes disclosed in application Ser. No. 11/753,546 filed May 24, 2007 are herein incorporated by reference. The curing step and the removing step may or may not be performed concurrently. If the curing and removing steps are not performed concurrently, the removing step may be performed before the curing process or may be performed after the curing process. Of course there can be other variations, modifications, and alternatives.

The present invention provides various embodiments of methods and systems for coupling a plurality of optical concentrators with a plurality of photovoltaic elements using coupling sheets with prearranged patterns of coupling regions. While these inventions have been described in the context of the above specific embodiments, modifications and variations are possible. Accordingly, the scope and breadth of the present invention should not be limited by the specific embodiments described above and should instead be determined by the following claims and their full extend of equivalents.

What is claimed is:

1. A method for fabricating a photovoltaic device, the method comprising:
providing a photovoltaic member having a plurality of photovoltaic elements, the plurality of photovoltaic elements including a first photovoltaic element and a second photovoltaic element;
providing a sheet member comprising a coupling material, the sheet member having a predefined pattern of coupling elements, the predefined pattern of coupling elements including a first coupling element and a second coupling element;
providing an optical concentrating member having a plurality of concentrating elements, the plurality of concentrating elements including a first concentrating element and a second concentrating element;
disposing the sheet member between the photovoltaic member and the optical concentrating member such that the first coupling element being positioned between the first photovoltaic element and the first concentrating element and such that the second coupling element is positioned between the second photovoltaic element and the second concentrating element; and
processing the sheet member between the photovoltaic member and the optical concentrating member using at least a curing process to cause the first photovoltaic element to be coupled to the first concentrating element and the second photovoltaic element to be coupled to the second concentrating element.

2. The method of claim 1 wherein the curing process comprises transforming the coupling material from a thermal plastic state to a thermal set state.

3. The method of claim 1 wherein the sheet member increases the efficiency of light transmission from the first concentrating element to the first photovoltaic element.

4. The method of claim 1 wherein the sheet member reduces a thermal mismatch effect of between the first photovoltaic element and the first concentrating element.

5. The method of claim 1 wherein the sheet member provides an environmental barrier between the photovoltaic member and the concentrating member.

6. The method of claim 1 wherein the curing process comprises applying a force to cause a force profile to the sheet member over a specified period of time.

7. The method of claim 1 wherein the curing process comprises applying a temperature profile to the sheet member over a specified period of time.

8. The method of claim 1 wherein the curing process comprises applying selected chemicals to the sheet member over a specified period of time.

9. The method of claim 1 wherein the process of disposing the sheet member between the photovoltaic member and the optical concentrating member comprises first placing the sheet member on the photovoltaic member followed by placing the concentrator member on the sheet member.

10. The method of claim 1 wherein the process of placing the sheet member between the photovoltaic member and the optical concentrating member comprises first placing the sheet member on the concentrator member followed by placing the photovoltaic member on the sheet member.

11. The method of claim 1 wherein the plurality of photovoltaic elements, the plurality of concentrating elements, and the plurality of coupling elements are arranged in a predetermined pattern.

12. The method of claim 1 wherein the plurality of photovoltaic elements, the plurality of concentrating elements, and the plurality of coupling elements are arranged in an array.

13. The method of claim 1 wherein the coupling material comprises an ethyl vinyl acetate (EVA) material.

14. The method of claim 1 wherein the coupling material comprises a PVA material.

15. The method of claim 1 wherein the coupling material comprises an APU material.

16. The method of claim 1 further comprising:
providing a first electrode member and a second electrode member;
coupling the first electrode member to the first photovoltaic element; and
coupling the second electrode member to the second photovoltaic element.

17. The method of claim 1 wherein the sheet member comprises at least a frame-structure portion and a patterned portion, the patterned portion including the predefined pattern of coupling elements.

18. The method of claim 17 wherein the frame-structure portion is coupled to the patterned portion, the frame-structure portion is adapted to allow the sheet member to be positioned and aligned between the photovoltaic member and the concentrating member.

19. The method of claim 18 further comprises removing the frame-structure portion from the patterned portion.

20. The method of claim 19 wherein the frame-structure portion is removed after the sheet member has been cured.

21. The method of claim 19 wherein the frame-structure portion is removed before the sheet member has been cured.

22. The method of claim 19 wherein the frame-structure portion is removed by a snapping motion or force.

23. The method of claim 19 wherein the frame-structure portion is removed by a twisting motion or force.

24. A sheet element for coupling together a photovoltaic member and a concentrating member, the photovoltaic member having a plurality of photovoltaic elements and the optical concentrating member having a plurality of concentrating elements, the sheet element comprising:
a patterned portion having a plurality of coupling elements arranged in a predefined pattern, the coupling elements surrounded by a filler region and the coupling elements being made of a first material; and
a frame-structure portion adapted for the sheet member to be:
positioned between the photovoltaic member and the concentrating member;
aligned with the optical concentrating member such that the plurality of coupling elements being lined up with the plurality of concentrating elements; and
aligned with the photovoltaic member such that the plurality of coupling elements being lined up with the plurality of photovoltaic elements.

25. The sheet member of claim 24 wherein the filler region comprises a second material.

26. The sheet member of claim 25 wherein the patterned portion is coupled to the frame-structure portion through the filler region.

27. The sheet member of claim 24 wherein the filler region comprises a void region.

28. The sheet member of claim 25 wherein the patterned portion is coupled to the frame-structure portion through a plurality of connectors provided on the frame-structure portion.

29. The sheet member of claim 24 wherein the coupling elements include a plurality of spacing elements.

30. The sheet member of claim 29 wherein the spacing elements is spherical in shape.

31. The sheet member of claim 29 wherein the spacing elements is cylindrical in shape.

32. The sheet member of claim 24 wherein the frame-structure portion is further adapted to be separated from the patterned portion.

33. The sheet member of claim 32 wherein the frame-structure portion is separated from the patterned portion by a snapping action.

34. The sheet member of claim 32 wherein the frame-structure portion is separated from the patterned portion by a twisting action.

35. The sheet member of claim 24 wherein the plurality of photovoltaic elements include a plurality of photovoltaic strips.
